(19) United States
(12) Patent Application Publication
(10) Pub. No.: US 2026/0202465 A1
(43) Pub. Date: Jul. 16, 2026

(54) TESTING METHOD AND TESTING DEVICE FOR ELECTRONIC CIRCUIT

(71) Applicant: United Microelectronics Corp., Hsinchu (TW)

(72) Inventor: Lu Qi, Sigapore (SG)

(73) Assignee: United Microelectronics Corp., Hsinchu (TW)

(21) Appl. No.: 19/051,051

(22) Filed: Feb. 11, 2025

(30) Foreign Application Priority Data
Jan. 10, 2025 (TW) 114101089

(51) Int. Cl. G01R 31/28

(52) U.S. Cl. CPC G01R 31/2841

(57) ABSTRACT

A testing method and a testing device for an electronic circuit are provided. The testing method includes the following steps. A test voltage signal is provided to a connection pad of the electronic circuit. A voltage regulating circuit of the electronic circuit is controlled to generate a reference voltage and provide the reference voltage to the connection pad. A voltage value of one of the test voltage signal and the reference voltage is adjusted, and a test current flowing through the connection pad is received. A measured voltage value of the reference voltage is determined according to a change in a current direction of the test current.

### CROSS-REFERENCE TO RELATED APPLICATION

This application claims the priority benefit of Taiwan application serial no. 114101089, filed on Jan. 10, 2025. The entirety of the above-mentioned patent application is hereby incorporated by reference herein and made a part of this specification.

### BACKGROUND

### Technical Field

The disclosure relates to a testing method and a testing device, and more particularly, to a testing method and a testing device for an electronic circuit.

### Description of Related Art

Generally speaking, a current testing method is to use a voltage measurement apparatus to receive a voltage value from a connection pad of an electronic circuit to determine whether a reference voltage generated by a voltage regulating circuit in the electronic circuit meets requirements of a customer. It should be noted that during a period when the voltage measurement apparatus receives the voltage value from the connection pad of the electronic circuit, the voltage measurement apparatus may pull down a voltage value at a measurement end (i.e., the connection pad) in a short time interval based on an internal protection mechanism. In such a protection mechanism, the reference voltage generated by the voltage regulating circuit of the electronic circuit will be pulled down, thereby causing abnormalities in the voltage regulating circuit of the electronic circuit.

Based on the above, how to optimize the testing method to avoid the abnormalities in the voltage regulating circuit of the electronic circuit is one of research key points for those skilled in the art.

### SUMMARY

The disclosure provides a testing method and a testing device for an electronic circuit, which may avoid abnormalities in a voltage regulating circuit of the electronic circuit during testing.

In an embodiment of the disclosure, a testing method includes the following steps. A test voltage signal is provided to a connection pad of the electronic circuit. A voltage regulating circuit of the electronic circuit is controlled to generate a reference voltage and provide the reference voltage to the connection pad. A voltage value of one of the test voltage signal and the reference voltage is adjusted, and a test current flowing through the connection pad is received. A measured voltage value of the reference voltage is determined according to a change in a current direction of the test current.

In an embodiment of the disclosure, a testing device includes a voltage generator, a controller, and a current sensor. The voltage generator is connected to a connection pad of the electronic circuit. The voltage generator provides a test voltage signal to the connection pad of the electronic circuit. The controller is connected to the electronic circuit. The controller controls the electronic circuit to generate a reference voltage and provide the reference voltage to the connection pad, and adjusts a voltage value of one of the test voltage signal and the reference voltage. The current sensor is connected to the connection pad. The current sensor receives a test current flowing through the connection pad. The controller determines a measured voltage value of the reference voltage according to a change in a current direction of the test current.

Based on the above, the testing method in the disclosure is to adjust the voltage value of one of the test voltage signal and the reference voltage, and receive the test current flowing through the connection pad. The testing method is to determine the measured voltage value of the reference voltage according to the change in the current direction of the test current. In the testing method, the voltage measurement apparatus is not used to receive the voltage value from the connection pad of the electronic circuit. Therefore, in the testing method, the voltage value at the connection pad is not pulled down based on the internal protection mechanism. In this way, the voltage regulating circuit of the electronic circuit will not occur the abnormalities due to the pull-down of the voltage value at the connection pad.

### BRIEF DESCRIPTION OF THE DRAWINGS

FIG. 1 is a schematic view of a testing device according to an embodiment of the disclosure.

FIG. 2 is a schematic view of a testing method according to an embodiment of the disclosure.

FIG. 3 is a schematic view of a testing method according to an embodiment of the disclosure.

FIG. 4 is a schematic view of a test according to an embodiment of the disclosure.

FIG. 5 is a schematic view of a testing method according to an embodiment of the disclosure.

FIG. 6 is a schematic view of a test according to an embodiment of the disclosure.

FIG. 7 is a test result according to an embodiment of the disclosure.

### DETAILED DESCRIPTION OF DISCLOSED EMBODIMENTS

Some embodiments of the disclosure will be described in detail with reference to the accompanying drawings. For reference numerals cited in the following descriptions, the same reference numerals appearing in different drawings are regarded as the same or similar components. The embodiments are only a part of the disclosure and do not disclose all possible implementations of the disclosure. More precisely, the embodiments are merely examples of the device and the method.

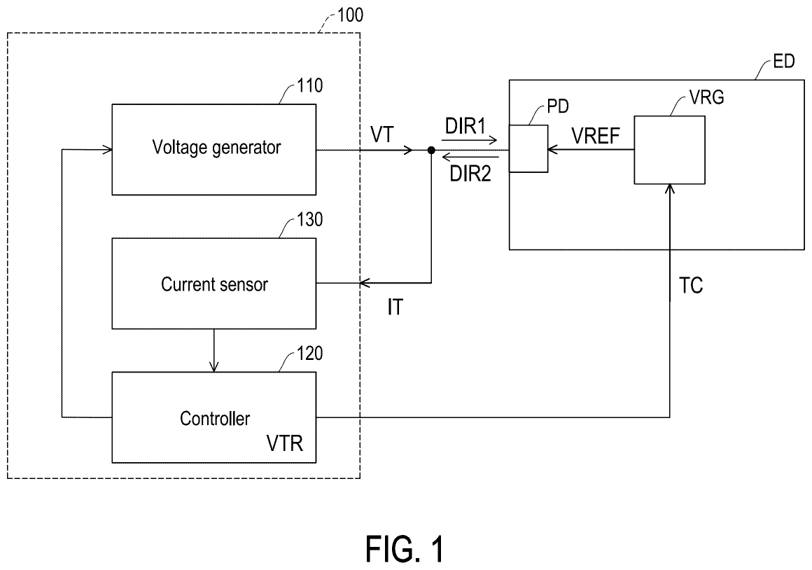

Referring to FIG. 1, FIG. 1 is a schematic view of a testing device according to an embodiment of the disclosure. In this embodiment, a testing device 100 includes a voltage generator 110, a controller 120, and a current sensor 130. The voltage generator 110 is connected to a connection pad PD of an electronic circuit ED. The voltage generator 110 provides a test voltage signal VT to the connection pad PD of the electronic circuit ED. The controller 120 is connected to the electronic circuit ED. The controller 120 controls the electronic circuit ED to generate a reference voltage VREF and provides the reference voltage VREF to the connection pad PD. In this embodiment, the controller 120 adjusts a voltage value of one of the test voltage signal VT and the reference voltage VREF.

For example, the electronic circuit ED includes a voltage regulating circuit VRG. The controller 120 controls the voltage regulating circuit VRG to generate the reference voltage VREF. The voltage regulating circuit VRG provides the reference voltage VREF to the connection pad PD.

For example, in an embodiment, the controller 120 may control the voltage generator 110 to adjust the voltage value of the test voltage signal VT. In another embodiment, the controller 120 may control the voltage regulating circuit VRG to adjust the voltage value of the reference voltage VREF.

In this embodiment, the current sensor 130 is connected to the connection pad PD. The current sensor 130 receives a test current IT flowing through the connection pad PD. The controller 120 determines a measured voltage value VTR of the reference voltage VREF according to a change in a current direction of the test current IT.

Generally speaking, a current testing method is to use a voltage measurement apparatus to receive a voltage value from the connection pad PD of the electronic circuit ED. However, during a period when the voltage measurement apparatus receives the voltage value from the connection pad PD of the electronic circuit ED, the voltage measurement apparatus may pull down the voltage value at the connection pad PD in a short time interval based on an internal protection mechanism. In such a protection mechanism, the reference voltage VREF generated by the voltage regulating circuit VRG of the electronic circuit ED will be pulled down, thereby causing abnormalities in the voltage regulating circuit VRG of the electronic circuit ED. It is worth mentioning here that the current sensor 130 in this embodiment may receive the test current IT flowing through the connection pad PD. The controller 120 determines the measured voltage value VTR of the reference voltage VREF according to the change of the current direction of the test current IT. Therefore, the testing device 100 does not pull down the voltage value at the connection pad PD based on the internal protection mechanism. In this way, the voltage regulating circuit VRG of the electronic circuit ED will not occur the abnormalities due to the pull-down of the voltage value at the connection pad PD.

For example, the electronic circuit ED may be a memory device, but the disclosure is not limited thereto. The memory device may be, for example, an embedded eFlash device in any type, but the disclosure is not limited thereto. The voltage regulating circuit VRG may be, for example, a low-dropout regulator (LDO), but the disclosure is not limited thereto.

In this embodiment, the controller 120 may obtain the current direction of the test current IT according to a current value of the test current IT. The controller 120 uses the voltage value corresponding to the change in the current direction of the test current IT as the measured voltage value VTR of the reference voltage VREF. The measured voltage value VTR is a real voltage value of the reference voltage VREF during testing.

In this embodiment, when the voltage value of the test voltage signal VT is higher than the voltage value of the reference voltage VREF, the test current IT has a first current direction DIR1. The first current direction DIR1 is a direction in which the test current IT flows from the testing device 100 into the electronic circuit ED. Therefore, the current value of the test current IT is a positive value. When the voltage value of the test voltage signal VT is lower than the voltage value of the reference voltage VREF, the test current IT has a second current direction DIR2. The second current direction DIR2 is a direction in which the test current IT flows from the electronic circuit ED into the testing device 100. Therefore, the current value of the test current IT is a negative value. The second current direction DIR2 is opposite to the first current direction DIR1. In addition, when the voltage value of the test voltage signal VT is equal to the voltage value of the reference voltage VREF, the current value of the test current IT is approximately equal to 0. Therefore, during a period of adjusting the voltage value of one of the test voltage signal VT and the reference voltage VREF, if the current direction of the test current IT changes, the controller 120 may use the voltage value corresponding to the change in the current direction of the test current IT as the measured voltage value VTR of the reference voltage VREF. For example, when the current value of the test current IT changes from a negative value to a positive value or 0, the controller 120 may use the voltage value of the current test voltage signal VT as the measured voltage value VTR of the reference voltage VREF. For example, when the current value of the test current IT changes from a positive value to a negative value or 0, the controller 120 may use the voltage value of the current test voltage signal VT as the measured voltage value VTR of the reference voltage VREF.

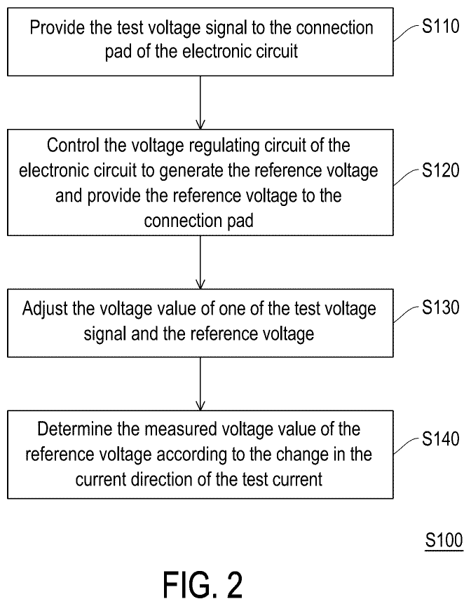

Referring to FIGS. 1 and 2, FIG. 2 is a schematic view of a testing method according to an embodiment of the disclosure. A testing method S100 is suitable for testing the electronic circuit ED. In this embodiment, the testing method S100 includes steps S110 to S140. In step S110, the voltage generator 110 provides the test voltage signal VT to the connection pad PD of the electronic circuit ED. In step S120, the controller 120 controls the voltage regulating circuit VRG of the electronic circuit ED to generate the reference voltage VREF and provides the reference voltage VREF to the connection pad PD. In step S130, the controller 120 adjusts the voltage value of one of the test voltage signal VT and the reference voltage VREF. In addition, the current sensor 130 receives the test current IT flowing through the connection pad PD in step S130. In step S140, the controller 120 determines the measured voltage value VTR of the reference voltage VREF according to the change in the current direction of the test current IT.

Steps S110 to S140 have been clearly described in the embodiment of FIG. 1. Therefore, the same details will not be repeated in the following.

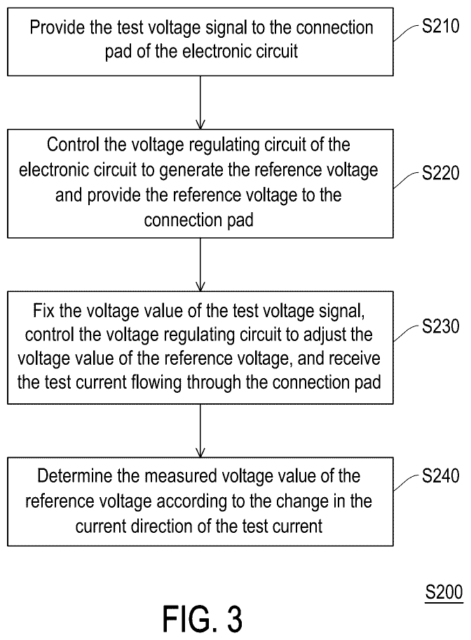

Referring to FIGS. 1 and 3, FIG. 3 is a schematic view of a testing method according to an embodiment of the disclosure. A testing method S200 is suitable for testing the electronic circuit ED. In this embodiment, the testing method S200 includes steps S210 to S240. In step S210, the voltage generator 110 provides the test voltage signal VT to the connection pad PD of the electronic circuit ED. In step S220, the controller 120 controls the voltage regulating circuit VRG of the electronic circuit ED to generate the reference voltage VREF and provides the reference voltage VREF to the connection pad PD. In step S230, the controller 120 controls the voltage generator 110 to fix the voltage value of the test voltage signal VT, and controls the voltage regulating circuit VRG to adjust the voltage value of the reference voltage VREF. In step S230, the current sensor 130 receives the test current IT flowing through the connection pad PD. In step S240, the controller 120 determines the measured voltage value VTR of the reference voltage VREF according to the change in the current direction of the test current IT.

For example, the voltage regulating circuit VRG generates the reference voltage VREF in response to a tuning code TC. The tuning code TC may be provided by the controller 120. The controller 120 controls the voltage regulating circuit VRG to generate the reference voltage VREF by using the tuning code TC in step S220. The controller 120 sweeps a code value of the tuning code TC in step S230, so that the voltage regulating circuit VRG sweeps the voltage value of the reference voltage VREF in step S230.

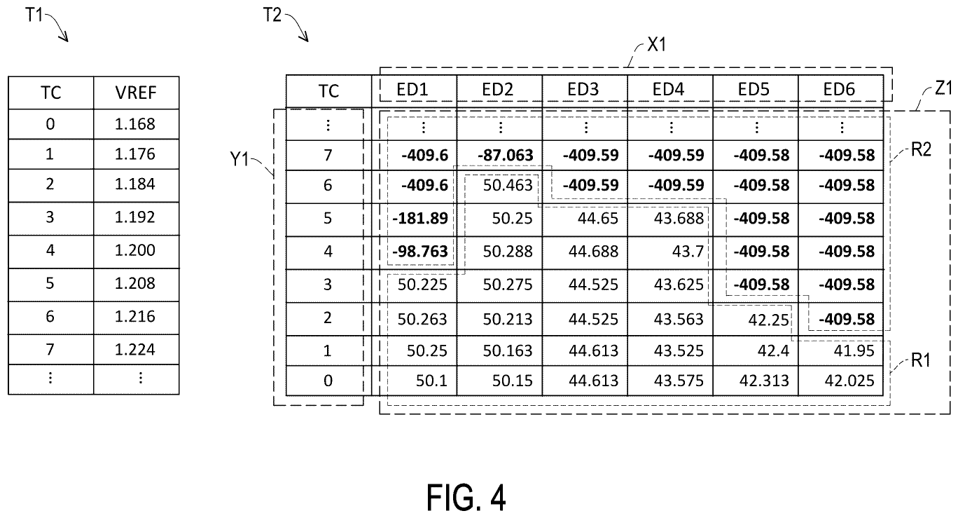

Referring to FIGS. 1, 3, and 4, FIG. 4 is a schematic view of a test according to an embodiment of the disclosure. In this embodiment, FIG. 4 shows a tuning table T1 and a test result T2 of the voltage regulating circuit VRG. The tuning table T1 records a relationship between the voltage value of the reference voltage VREF of the voltage regulating circuit VRG and the tuning code TC. The code value of the tuning code TC corresponds to the voltage value of the reference voltage VREF. The code value of the tuning code TC is, for example, proportional to the voltage value of the reference voltage VREF (however, the disclosure is not limited thereto). The tuning code TC and the voltage value of the reference voltage VREF in the tuning table T1 are only examples, but the disclosure is not limited thereto. It should be noted that in actual situations, actual operation results of the voltage regulating circuit VRG may be different from contents of the tuning table T1. Therefore, the testing method S200 is required to be performed to determine the actual operation results of the voltage regulating circuit VRG.

In the test result T2, in a field X1, electronic circuits ED1 to ED6 to be tested are listed. In a field Y1, the code values of the tuning code TC are listed. A field Z1 shows the current values of the test current IT (unit: microampere).

In this embodiment, the controller 120 fixes the voltage value of the test voltage signal VT. The voltage regulating circuit VRG sequentially sweeps the voltage values of the reference voltage VREF from low to high in response to the code value of the tuning code TC. The controller 120 collects the current value of the test current IT and determines the measured voltage values VTR of the electronic circuits ED1 to ED6. The controller 120 may determine the change in the current direction of the test current IT according to a change in the positive and negative values of the current value of the test current IT, and determine the measured voltage value VTR of the reference voltage VREF according to the change in the current direction of the test current IT.

When the voltage value of the test voltage signal VT is higher than the voltage value of the reference voltage VREF, the test current IT has the first current direction DIR1. The current value of the test current IT is, for example, a positive value. When the voltage value of the test voltage signal VT is lower than the voltage value of the reference voltage VREF, the test current IT has the second current direction DIR2. The current value of the test current IT is, for example, a negative value. Therefore, a region R1 in the test result T2 indicates that the test current IT has the first current direction DIR1. A region R2 in the test result T2 indicates that the test current IT has the second current direction DIR2.

In this embodiment, the voltage regulating circuit VRG sequentially sweeps the voltage values of the reference voltage VREF from low to high in response to the code value of the tuning code TC. Therefore, the controller 120 may learn that the voltage value corresponding to the code value entering a boundary of the region R2 is equal to the voltage value of the fixed test voltage signal VT (i.e., the measured voltage value VTR).

Taking the electronic circuit ED2 as an example, when the code value of the tuning code TC rises to “7”, the current direction of the test current IT changes. Therefore, the voltage value corresponding to the code value of the tuning code TC being equal to “7” is approximately equal to the voltage value of the fixed test voltage signal VT. Therefore, the controller 120 obtains the measured voltage value VTR of the reference voltage VREF according to the voltage value corresponding to the code value of the tuning code TC being equal to “7”. For example, the voltage value of the test voltage signal VT is fixed at 1.15 volts. The voltage value corresponding to the code value of the tuning code TC being equal to “7” is 1.224 volts. Therefore, the measured voltage value VTR corresponding to the code value of the tuning code TC being equal to “7” corresponding to the electronic circuit ED2 should be corrected to 1.15 volts. In order for the voltage regulating circuit VRG of the electronic circuit ED2 to provide the reference voltage VREF with 1.224 volts, the tuning code TC is required to be shifted (e.g., increased).

Taking the electronic circuit ED6 as an example, when the code value of the tuning code TC rises to “2”, the current direction of the test current IT changes. Therefore, the voltage value corresponding to the code value of the tuning code TC being equal to “2” is approximately equal to the voltage value of the fixed test voltage signal VT. Therefore, the controller 120 obtains the measured voltage value VTR of the reference voltage VREF according to the voltage value corresponding to the code value of the tuning code TC being equal to “2”. For example, the voltage value of the test voltage signal VT is fixed at 1.15 volts. The voltage value corresponding to the code value of the tuning code TC being equal to “2” is 1.184 volts. Therefore, the measured voltage value VTR corresponding to the code value of the tuning code TC being equal to “2” corresponding to the electronic circuit ED2 should be corrected to 1.15 volts. In order for the voltage regulating circuit VRG of the electronic circuit ED6 to provide the reference voltage VREF with 1.184 volts, the tuning code TC is required be shifted (e.g., increased).

Based on the above, the controller 120 may further learn that the electronic circuit ED2 has a larger offset than the electronic circuit ED6.

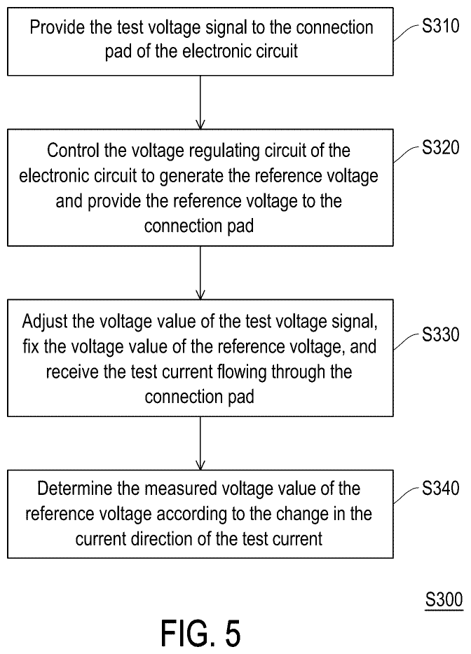

Referring to FIGS. 1 and 5, FIG. 5 is a schematic view of a testing method according to an embodiment of the disclosure. In this embodiment, a testing method S300 includes steps S310 to S340. In step S310, the voltage generator 110 provides the test voltage signal VT to the connection pad PD of the electronic circuit ED. In step S320, the controller 120 controls the voltage regulating circuit VRG of the electronic circuit ED to generate the reference voltage VREF and provides the reference voltage VREF to the connection pad PD. In step S330, the controller 120 controls the voltage generator 110 to adjust the voltage value of the test voltage signal VT, and controls the voltage regulating circuit VRG to fix the voltage value of the reference voltage VREF. The current sensor 130 receives the test current IT flowing through the connection pad PD in step S330. In step S340, the controller 120 determines the measured voltage value VTR of the reference voltage VREF according to the change in the current direction of the test current IT.

For example, the voltage regulating circuit VRG generates the fixed reference voltage VREF in response to the fixed tuning code TC. The controller 120 controls the voltage regulating circuit VRG to generate the reference voltage VREF by using the tuning code TC in step S220. The controller 120 controls the voltage generator 110 in step S330, so that the voltage generator 110 is controlled to sweep the voltage value of the test voltage signal VT in step S330.

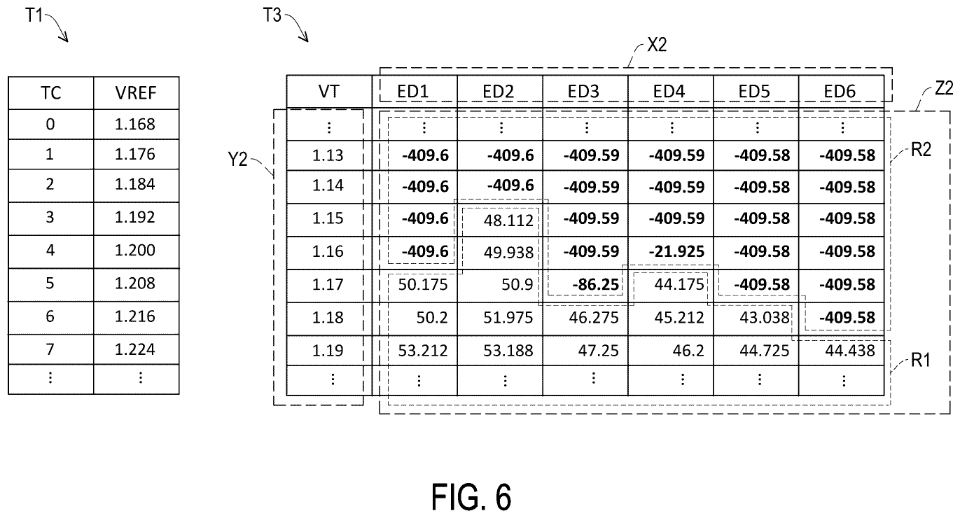

Referring to FIGS. 1, 5, and 6, FIG. 6 is a schematic view of a test according to an embodiment of the disclosure. In this embodiment, FIG. 6 shows the tuning table T1 and a test result T3. The tuning table T1 records the relationship between the voltage value of the reference voltage VREF of the voltage regulating circuit VRG and the tuning code TC. The code value of the tuning code TC corresponds to the voltage value of the reference voltage VREF. The code value of the tuning code TC is, for example, proportional to the voltage value of the reference voltage VREF (but the disclosure is not limited thereto). The tuning code TC and the voltage value of the reference voltage VREF in the tuning table T1 are only examples, but the disclosure is not limited thereto. It should be noted that in the actual situations, the actual operation results of the voltage regulating circuit VRG may be different from the contents of the tuning table T1. Therefore, the testing method S300 is required to be performed to determine the actual operation results of the voltage regulating circuit VRG.

In the test result T3, in a field X2, the electronic circuits ED1 to ED6 to be tested are listed. In a field Y2, different voltage values of the test voltage signal VT are listed. A field Z2 shows the current values of the test current IT.

In this embodiment, the controller 120 fixes the code value of the tuning code TC. Therefore, the voltage value of the reference voltage VREF is fixed. The voltage generator 110 sequentially sweeps the voltage values of the test voltage signal VT from low to high. The controller 120 collects the current value of the test current IT and determines the measured voltage values VTR of the electronic circuits ED1 to ED6. The controller 120 may determine the change in the current direction of the test current IT according to the change in the positive and negative values of the current value of the test current IT, and determine the measured voltage value VTR of the reference voltage VREF according to the change in the current direction of the test current IT.

When the voltage value of the test voltage signal VT is higher than the voltage value of the reference voltage VREF, the test current IT has the first current direction DIR1. When the voltage value of the test voltage signal VT is lower than the voltage value of the reference voltage VREF, the test current IT has the second current direction DIR2. Therefore, the region R1 in the test result T2 indicates that the test current IT has the first current direction DIR1. The region R2 in the test result T2 indicates that the test current IT has the second current direction DIR2.

In this embodiment, the controller 120 sequentially sweeps the voltage values of the test voltage signal VT from low to high. Therefore, the controller 120 may learn that the voltage value of the code value of the fixed tuning code TC is equal to the voltage value of the test voltage signal VT (i.e., the measured voltage value VTR).

Taking the electronic circuit ED2 as an example, when the voltage value of the test voltage signal VT rises to 1.15 volts, the current direction of the test current IT changes. Therefore, the measured voltage value VTR corresponding to the reference voltage VREF of the fixed tuning code TC is approximately equal to 1.15 volts. Taking the electronic circuit ED6 as an example, when the voltage value of test voltage signal VT rises to 1.19 volts, the current direction of the test current IT changes. Therefore, the measured voltage value VTR corresponding to the reference voltage VREF of the fixed tuning code TC is approximately equal to 1.19 volts.

Based on the above, in a case of the same code value of the fixed tuning code TC, the controller 120 may further learn that the voltage value of the reference voltage VREF of the electronic circuit ED2 is lower than the voltage value of the reference voltage VREF of the electronic circuit ED6.

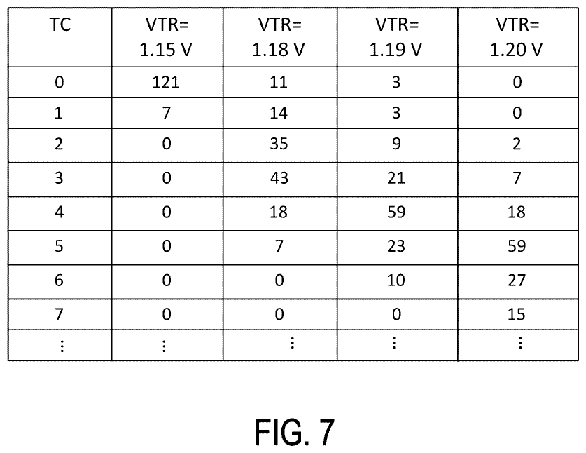

Referring to FIGS. 1, 3, 5, and 7, FIG. 7 is a test result according to an embodiment of the disclosure. In this embodiment, FIG. 7 shows test results of 128 electronic circuits from the same wafer. In a field X3, the measured voltage values VTR are listed. In a field Y3, the code values of the tuning code TC are listed. A field Z3 shows the number of electronic circuits conforming to the code values of the tuning code TC and the measured voltage values.

In addition, based on the testing methods S200 and S300, FIG. 7 may be a distribution diagram of the measured voltage values VTR of the reference voltages VREF of the 128 electronic circuits. This distribution diagram is used to illustrate that when the measured voltage value VTR changes, distribution of the corresponding tuning code TC will also move accordingly, proving that a trend of measurement results is in line with expectations. The 128 electronic circuits in FIG. 7 may come from the same wafer or the same production lot. In a case where the measured voltage values VTR of the reference voltages VREF of the 128 electronic circuits are obtained, in this embodiment, a yield rate of more than 97% may be achieved. Furthermore, FIG. 7 in this embodiment may show the test results performed based on a specific test temperature. The specific test temperature may be temperature from 25° C. to 125° C. Therefore, this embodiment is suitable for testing electronic circuits used in automotive, industrial, or aerospace fields.

Based on the above, the testing method is to adjust the voltage value of one of the test voltage signal and the reference voltage, and receive the test current flowing through the connection pad. The testing method is to determine the measured voltage value of the reference voltage according to the change in the current direction of the test current. The testing method does not require the use of the voltage measurement apparatus to receive the voltage value from the connection pad of the electronic circuit. Therefore, in the testing method, the voltage value at the connection pad is not pulled down based on the internal protection mechanism of the voltage measurement apparatus. In this way, the voltage regulating circuit of the electronic circuit will not have the abnormalities due to the pull-down of the voltage value at the connection pad.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A testing method for an electronic circuit, comprising:
providing a test voltage signal to a connection pad of the electronic circuit;
controlling a voltage regulating circuit of the electronic circuit to generate a reference voltage and providing the reference voltage to the connection pad;
adjusting a voltage value of one of the test voltage signal and the reference voltage, and receiving a test current flowing through the connection pad; and
determining a measured voltage value of the reference voltage according to a change in a current direction of the test current.

2. The testing method according to claim 1, wherein a step of adjusting the voltage value of one of the test voltage signal and the reference voltage comprises:
fixing the voltage value of the test voltage signal, and adjusting the voltage value of the reference voltage.

3. The testing method according to claim 2, wherein the voltage regulating circuit generates the reference voltage in response to a tuning code.

4. The testing method according to claim 3, wherein a step of adjusting the voltage value of the reference voltage comprises:
sweeping a code value of the tuning code such that the voltage regulating circuit sweeps the voltage value of the reference voltage.

5. The testing method according to claim 1, wherein a step of adjusting the voltage value of one of the test voltage signal and the reference voltage comprises:
fixing the voltage value of the reference voltage, and adjusting the voltage value of the test voltage signal.

6. The testing method according to claim 5, wherein a step of adjusting the voltage value of the test voltage signal comprises:
sweeping the voltage value of the test voltage signal.

7. The testing method according to claim 1, wherein a step of determining the measured voltage value of the reference voltage according to the change in the current direction of the test current comprises:
using a voltage value corresponding to the change in the current direction as the measured voltage value of the reference voltage.

8. The testing method according to claim 1, wherein when the voltage value of the test voltage signal is higher than the voltage value of the reference voltage, the test current has a first current direction.

9. The testing method according to claim 8, wherein when the voltage value of the test voltage signal is lower than the voltage value of the reference voltage, the test current has a second current direction opposite to the first current direction.

10. The testing method according to claim 1, wherein when the voltage value of the test voltage signal is equal to the voltage value of the reference voltage, a current value of the test current is equal to 0.

11. A testing device for an electronic circuit, comprising:
a voltage generator connected to a connection pad of the electronic circuit and configured to provide a test voltage signal to the connection pad of the electronic circuit;
a controller connected to the electronic circuit, and configured to control the electronic circuit to generate a reference voltage and provide the reference voltage to the connection pad, and adjust a voltage value of one of the test voltage signal and the reference voltage; and
a current sensor connected to the connection pad and configured to receive a test current flowing through the connection pad,
wherein the controller determines a measured voltage value of the reference voltage according to a change in a current direction of the test current.

12. The testing device according to claim 11, wherein the controller fixes the voltage value of the test voltage signal and adjusts the voltage value of the reference voltage.

13. The testing device according to claim 12, wherein
the controller provides a tuning code, and
a voltage regulating circuit of the electronic circuit generates the reference voltage in response to the tuning code.

14. The testing device according to claim 13, wherein the controller sweeps a code value of the tuning code, so that the voltage regulating circuit sweeps the voltage value of the reference voltage.

15. The testing device according to claim 11, wherein the controller fixes the voltage value of the reference voltage and adjusts the voltage value of the test voltage signal.

16. The testing device according to claim 15, wherein the controller controls the voltage generator to sweep the voltage value of the test voltage signal.

17. The testing device according to claim 11, wherein the controller uses a voltage value corresponding to the change in the current direction as the measured voltage value of the reference voltage.

18. The testing device according to claim 11, wherein when the voltage value of the test voltage signal is higher than the voltage value of the reference voltage, the test current has a first current direction.

19. The testing device according to claim 18, wherein when the voltage value of the test voltage signal is lower than the voltage value of the reference voltage, the test current has a second current direction opposite to the first current direction.

20. The testing device according to claim 11, wherein when the voltage value of the test voltage signal is equal to the voltage value of the reference voltage, a current value of the test current is equal to 0.
